(19) United States
(12) Patent Application Publication
(10) Pub. No.: US 2026/0136801 A1
(43) Pub. Date: May 14, 2026

(54) DISPLAY DEVICE AND METHOD FOR MANUFACTURING DISPLAY DEVICE

(71) Applicant: SHARP KABUSHIKI KIASHA, Sakai City (JP)

(72) Inventors: MASAYUKI KANEHIRO, Sakai City (JP); TAKESHI ISHIDA, Sakai City (JP); Yohei NAKANISHI, Sakai City (JP)

(21) Appl. No.: 19/434,244

(22) Filed: Dec. 29, 2025

Related U.S. Application Data
(63) Continuation of application No. 17/792,807, now abandoned.

(51) Int. Cl. H10K 59/38; H10K 50/115; H10K 50/15; H10K 59/12; H10K 59/80

(52) U.S. Cl. CPC H10K 59/38; H10K 50/115; H10K 50/15; H10K 59/8731; H10K 59/1201

(57) ABSTRACT

In a red sub-pixel of a display device according to an aspect of the disclosure, an anode, a red hole-transport layer, a red light-emitting layer, an intermediate layer, an electron-transport layer, and a cathode are stacked on top of another in a stated order. A peak emission wavelength of blue quantum dots contained in the intermediate layer is shorter than a peak emission wavelength of red quantum dots contained in the red light-emitting layer.

### CROSS-REFERENCE TO RELATED APPLICATION

The present application is a continuation application of U.S. patent application Ser. No. 17/792,807, filed on Jul. 14, 2022, which is the National Stage of International Application No. PCT/JP2020/003525, filed on Jan. 30, 2020, the content of which is hereby incorporated by reference into this application.

### TECHNICAL FIELD

The disclosure relates to a display device and a method for manufacturing the display device.

### BACKGROUND ART

In recent years, various kinds of flat display panels are being developed. In particular, display devices including quantum-dot light-emitting diodes (QLEDs) or organic light-emitting diodes (OLEDs) are attracting attention.

Patent Document 1 relates to a light-emitting element including a light-emitting layer formed of a monolayer containing quantum dots. In forming the light-emitting layer, the quantum dots are phase-separated from a liquid mixture of the quantum dots and a hole-transport material that forms a hole-transport layer.

### CITATION LIST

### Patent Literature

[Patent Document 1] Japanese Unexamined Patent Publication Application No. 2009-088276 (Published on Apr. 23, 2009)

### SUMMARY

### Technical Problems

For a known display device including the above light-emitting element, a light-emitting layer and a hole-transport layer are formed for each of the colors R, G, and B not by a known vapor deposition technique, but with the above liquid mixture. This is to simplify the manufacturing steps and produce the display device at lower costs.

However, in the above known display device, the light-emitting layer exhibits uneven distribution of the phase-separated quantum dots. Moreover, the light-emitting layer produces a spot where the quantum dots are excessively few, and the hole-transport material is exposed to the surface of the light-emitting layer. As a result, in this known display device, the exposed hole-transport material might be in contact with an electron-transporting material of the electron-transport layer provided across from the hole-transport layer of the light-emitting layer, and/or with a cathode material inside an electron-transport layer also serving as a cathode. The contact would cause a leak between the hole-transport material and both of, or either, the electron-transporting material and/or the cathode material. Such a leak could pose a problem that the quantum dots in the light-emitting layer fail to emit light, causing a decrease in light emission efficiency of the display device.

In view of the above problems, the disclosure is intended to improve light emission efficiency of a display device.

### Solution to Problems

In order to solve the above problems, a display device according to an aspect of the disclosure includes: a display region including a plurality of pixels, and a frame region outside the display region; and a thin-film transistor layer, a light-emitting-element layer including a plurality of light-emitting elements each emitting a light in a different color, and a sealing layer sealing the light-emitting-element layer. Each of the light-emitting elements includes an anode, a first hole-transport layer, a light-emitting layer containing quantum dots, an electron-transport layer, and a cathode in a stated order. One of the anode and the cathode is an island electrode provided for each of the light-emitting elements, and another one of the anode and the cathode is a common electrode provided in common among the light-emitting elements. At least one of the light-emitting elements further includes an intermediate layer provided between the light-emitting layer and the electron-transport layer, and containing quantum dots a peak emission wavelength of which is shorter than a peak emission wavelength of the quantum dots contained in the light-emitting layer.

In order to solve the above problems, in a method for manufacturing a display device, the display device includes: a display region including a plurality of pixels, and a frame region outside the display region; and a thin-film transistor layer, a light-emitting-element layer including a plurality of light-emitting elements each emitting a light in a different color, and a sealing layer sealing the light-emitting-element layer. At least one of the pixels is provided with: a red light-emitting element emitting light a color of which is red; a green light-emitting element emitting light a color of which is green; and a blue light-emitting element emitting light a color of which is blue. The red light-emitting element, the green light-emitting element, and the blue light-emitting element are included in the light-emitting elements. The method includes: a red application step of applying a red coating liquid to a region of the red light-emitting element, a region of the green light-emitting element, and a region of the blue light-emitting element, the red coating liquid containing red quantum dots emitting the red light, a hole-transport material monomer, and a photopolymerization initiator; a red phase-separation step of phase-separating the red coating liquid into a layer containing the red quantum dots and a layer not containing the red quantum dots; a red exposure step of exposing, to light, the red coating liquid into a pattern, to solidify a portion, of the red coating liquid, applied to the region of the red light-emitting element; a green application step of applying a green coating liquid to the region of the red light-emitting element, the region of the green light-emitting element, and the region of the blue light-emitting element, the green coating liquid containing green quantum dots emitting the green light, a hole-transport material monomer, and a photopolymerization initiator; a green phase-separation step of phase-separating the green coating liquid into a layer containing the green quantum dots and a layer not containing the green quantum dots; a green exposure step of exposing, to light, the green coating liquid into a pattern, to solidify a portion, of the green coating liquid, applied to the region of the green light-emitting element; and an intermediate layer forming step of forming an intermediate layer to cover the portion of which the red coating liquid is solidified and the portion of which the green coating liquid is solidified, the intermediate portion containing either blue quantum dots emitting the blue light, or quantum dots a peak emission wavelength of which is shorter than a peak emission wavelength of the blue quantum dots.

### Advantageous Effects of Disclosure

According to a display device according to an aspect of the disclosure, and a method for manufacturing the display device, light emission efficiency of the display device can improve.

### BRIEF DESCRIPTION OF DRAWINGS

FIG. 1 is a flowchart showing an example of a method for manufacturing a display device.

FIG. 2 is a cross-sectional view of an exemplary configuration of a display region of the display device.

FIG. 3 is a cross-sectional view of a schematic configuration of an active layer of the display device according to a first embodiment of the disclosure.

FIG. 4 is a cross-sectional view showing how a red coating liquid is dispersed to form a red hole-transport layer and a red light-emitting layer illustrated in FIG. 3.

FIG. 5 is a cross-sectional view showing how the red coating liquid is subjected to phase separation to form the red hole-transport layer and the red light-emitting layer illustrated in FIG. 3.

FIG. 6 is a schematic diagram illustrating a red hole-transport layer illustrated in FIG. 3, red quantum dots contained in a red light-emitting layer, blue quantum dots contained in an intermediate layer, and an energy level of an electron transport layer.

FIG. 7 is a flowchart showing a process of forming the active layer illustrated in FIG. 3.

FIG. 8 is a schematic cross-sectional view of the active layer illustrated in FIG. 3 at a step of the forming process.

FIG. 9 is a schematic cross-sectional view of the active layer illustrated in FIG. 3 at a step of the forming process.

FIG. 10 is a schematic cross-sectional view of the active layer illustrated in FIG. 3 at a step of the forming process.

FIG. 11 is a schematic cross-sectional view of the active layer illustrated in FIG. 3 at a step of the forming process.

FIG. 12 is a schematic cross-sectional view of the active layer illustrated in FIG. 3 at a step of the forming process.

FIG. 13 is a schematic cross-sectional view of the active layer illustrated in FIG. 3 at a step of the forming process.

FIG. 14 is a schematic cross-sectional view of the active layer illustrated in FIG. 3 at a step of the forming process.

FIG. 15 is a schematic cross-sectional view of the active layer illustrated in FIG. 3 at a step of the forming process.

FIG. 16 is a schematic cross-sectional view of the active layer illustrated in FIG. 3 at a step of the forming process.

FIG. 17 is a schematic cross-sectional view showing a relationship between the red light-emitting layer and the electron-transport layer in the light-emitting element according to Example 1.

FIG. 18 is a schematic cross-sectional view showing a relationship between the red light-emitting layer and the electron-transport layer in the light-emitting element according to Comparative Example 1.

FIG. 19 is a schematic cross-sectional view showing a relationship between the red light-emitting layer and the electron-transport layer in the light-emitting element according to Comparative Example 2.

FIG. 20 is a schematic cross-sectional view showing a relationship between the red light-emitting layer and the electron-transport layer in the light-emitting element according to Comparative Example 3.

FIG. 21 is a table showing evaluations of the light-emitting elements according to Examples 1 to 3 and Comparative Examples 1 to 5.

FIG. 22 is a graph showing a relationship between the applied voltage and the current density of each of the light-emitting elements according to Examples 1 and 3 and Comparative Examples 1 to 3.

FIG. 23 is a graph showing a relationship between the applied voltage and the normalized luminance of emitted light of each of the light-emitting elements according to Examples 1 and 3 and Comparative Examples 1 to 3.

FIG. 24 is a graph of emission spectrums measured and normalized when voltages of 2.2 V, 2.9 V, 3.6 V, 4.1 V and 5.0 V are applied to the light-emitting element according to Example 1.

FIG. 25 is a cross-sectional view of a schematic configuration of the active layer of a display device according to a second embodiment of the disclosure.

FIG. 26 is a flowchart showing a process of forming the active layer illustrated in FIG. 25.

FIG. 27 is a schematic cross-sectional view of the active layer illustrated in FIG. 25 at a step of the forming process.

FIG. 28 is a schematic cross-sectional view of the active layer illustrated in FIG. 25 at a step of the forming process.

FIG. 29 is a schematic cross-sectional view of the active layer illustrated in FIG. 25 at a step of the forming process.

FIG. 30 is a schematic cross-sectional view of the active layer illustrated in FIG. 25 at a step of the forming process.

### DESCRIPTION OF EMBODIMENTS

### Method for Manufacturing Display Device, and Configuration of Display Device

In the description below, the term “same layer” means that constituent features are formed in the same process (in the same film forming step). The term “lower layer” means that a constituent feature is formed in a previous process before a comparative layer. The term “upper layer” means that a constituent feature is formed in a successive process after a comparative layer.

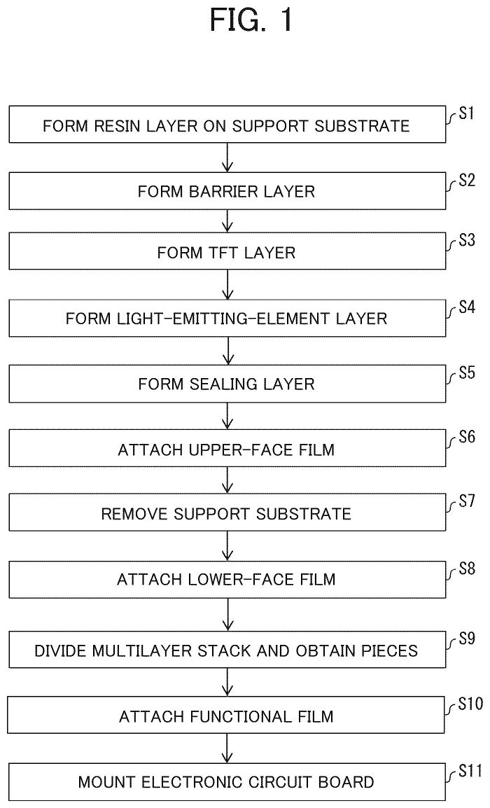

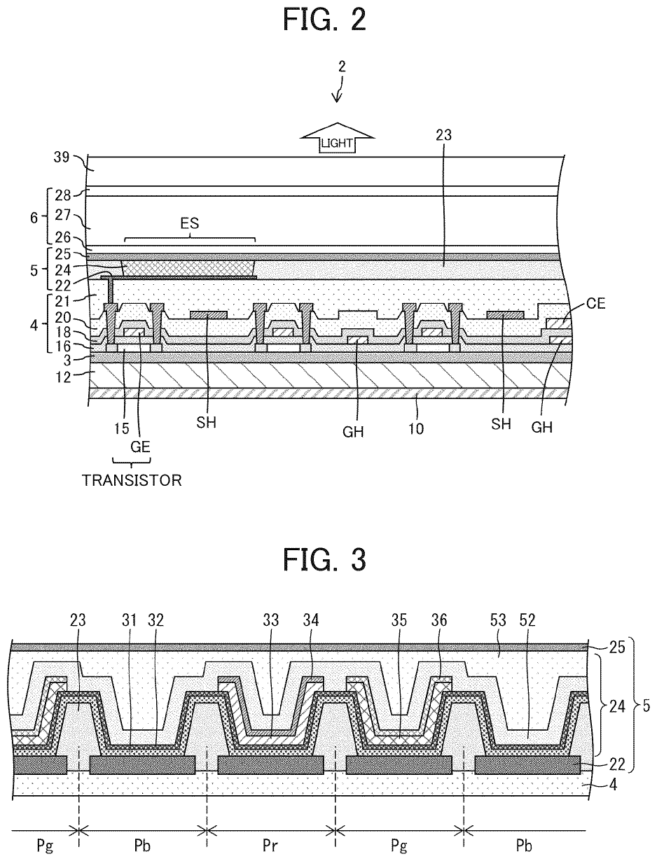

FIG. 1 is a flowchart showing an example of a method for manufacturing a display device. FIG. 2 is a schematic cross-sectional view of an exemplary configuration of a display region of a display device 2.

In producing a flexible display device as seen in FIGS. 1 and 2, first, at Step S1, a resin layer 12 is formed on a light-transparent support substrate (e.g. a mother glass). At Step S2, a barrier layer 3 is formed. At Step S3, a thin-film transistor layer 4 (a TFT layer) is formed. At Step S4, a light-emitting-element layer 5 of a top emission type is formed. At Step S5, a sealing layer 6 is formed. At Step S6, an upper-face film is attached to the sealing layer 6.

At Step S7, the support substrate is removed from the resin layer 12 with, for example, a laser beam emitted on the support substrate. At Step S8, a lower-face film 10 is attached to a lower face of the resin layer 12. At Step S9, a multilayer stack including the lower-face film 10, the resin layer 12, the barrier layer 3, the TFT layer 4, the light-emitting-element layer 5, and the sealing layer 6 is divided into a plurality of pieces. At Step S10, to each of the obtained pieces, a functional film 39 is attached. At Step S11, an electronic circuit board (e.g. an IC chip and an FPC) is mounted on a portion (a terminal unit) outside (a non-display region, a frame region) a display region in which a plurality of sub-pixels are formed. Note that Steps S1 to S11 are carried out on a display device manufacturing apparatus (including a deposition apparatus carrying out each of Steps S1 to S5).

An exemplary material of the resin layer 12 includes polyimide. The resin layer 12 can be replaced with a double-layer resin film (e.g. a polyimide film), and with an inorganic insulating film sandwiched between the resin layers.

The barrier layer 3 keeps the TFT layer 4 and the light-emitting-element layer 5 from such foreign objects as water and oxygen. The barrier layer 3 can be, for example, a silicon oxide film, a silicon nitride film, or a silicon oxide nitride film formed by chemical vapor deposition (CVD). Alternatively, the barrier layer 3 can be formed of a multilayer film including these films.

The TFT layer 4 includes: a semiconductor film 15; an inorganic insulating film 16 (a gate insulating film) above the semiconductor film 15; a gate electrode GE and a gate wire GH1 both above the inorganic insulating film 16; an inorganic insulating film 18 (an interlayer insulating film) above the gate electrode GE and the gate wire GH; a capacitance electrode CE above the inorganic insulating film 18; an inorganic insulating film 20 (an interlayer insulating film) above the capacitance electrode CE; a source wire SH above the inorganic insulating film 20; and a planarization film 21 (an interlayer insulating film) above the source wire SH.

The semiconductor layer 15 is formed of, for example, low-temperature polysilicon (LTPS) or oxide semiconductor (e.g. an In—Ga—Zn—O-based semiconductor). In FIG. 2, the transistors are formed in a top-gate structure; however, the transistors may be formed in a bottom-gate structure.

Each of the gate electrode GE, the gate wire GH, the capacitance electrode CE, and the source wire SH is a monolayer film made of at least one of such metals as, for example, aluminum, tungsten, molybdenum, tantalum, chromium, titanium, and copper. Alternatively, each of the electrodes and wires is a multilayer film formed of these metals.

Each of the inorganic insulating films 16, 18, and 20 can be, for example, a silicon oxide (SiOₓ) film, a silicon nitride (SiNₓ) film, or a silicon oxide nitride (SiNO) film formed by the CVD. Alternatively, each of the inorganic insulating films 16, 18, and 20 can be a multilayer film including these films. The planarization film 21 can be made of, for example, an applicable organic material such as polyimide and acrylic.

The light-emitting-element layer 5 includes: an anode 22 provided above the planarization film 21; an edge cover 23 insulative and covering an edge of the anode 22; an active layer 24 provided above the edge cover and serving as an electroluminescence (EL) layer; and a cathode 25 provided above the active layer 24. The edge cover 23 is formed of, for example, an organic material such as polyimide and acrylic. The organic material is applied and patterned by photolithography to form the edge cover 23. One of the anode 22 and the cathode 25 is an island electrode (i.e. a “pixel electrode”) provided for each of the light-emitting elements. Another one of the anode 22 and the cathode 25 is a common electrode provided in common among the light-emitting elements.

For each of the sub-pixels, a light-emitting element ES (an electroluminescence element) is formed in the light-emitting-element layer 5. The light-emitting element ES, which is a quantum-dot light-emitting diode (QLED), includes the anode 22 and the active layer 24 each shaped into an island, and the cathode 25. A sub-pixel circuit is formed in the TFT layer 4 to control the light-emitting element ES.

The active layer 24 includes a hole-injection layer, a hole-transport layer, a light-emitting layer, an electron-transport layer, and an electron-injection layer stacked on top of another in the stated order from below. The active layer 24 will be described later in detail. The light-emitting layer is shaped into an island and formed together with the hole-transport layer by photolithography for an opening of the edge cover 23 (for each sub-pixel). The other layers are each shaped into either an island or a monolithic form (a common layer). Moreover, one or more of the hole-injection layer, the hole-transport layer, and the electron-injection layer can be omitted.

The active layer 24 further includes an intermediate layer provided between the light-emitting layer and the electron-transport layer. The intermediate layer will be described later in detail.

The anode 22, which reflects light, is a reflective electrode. The anode 22 is formed of, for example, indium tin oxide (ITO) and either silver (Ag) or an alloy containing Ag stacked on top of another. Alternatively, the anode 22 is formed of a material containing Ag or Al. The cathode 25 is a transparent electrode formed of a light-transparent conductive material such as a thin film made of Ag, Au, Pt, Ni, and Ir, a thin film of a MgAg alloy, ITO, and indium zinc oxide (IZO). If the display device is not of the top emission type but of the bottom emission type, the lower-face film 10 and the resin layer 12 are transparent to light, the anode 22 is a transparent electrode, and the cathode 25 is a reflective electrode.

In the light-emitting element ES, holes and electrons recombine together in the light-emitting layer by a drive current between the anode 22 and the cathode 25, which forms an exciton. While the exciton transforms from the lowest unoccupied molecular orbital (LUMO) or the conduction band of the quantum dots to the highest occupied molecular orbital (HOMO) or the valence band, light is released.

The sealing layer 6, which is light-transparent, includes: an inorganic sealing film 26 covering the cathode 25; an organic buffer film 27 provided above the inorganic sealing film 26; and an inorganic sealing film 28 provided above the organic buffer film 27. The sealing layer 6 covering the light-emitting-element layer 5 seals the light-emitting-element layer 5 to keep the light-emitting-element 5 from such foreign objects as water and oxygen.

The inorganic sealing film 26 and the inorganic sealing film 28 are inorganic insulating films. Each of the inorganic sealing film 26 and the inorganic sealing film 28 can be formed of, for example, a silicon oxide film, a silicon nitride film, or a silicon oxide nitride film formed by the CVD. Alternatively, each of the inorganic sealing film 26 and the inorganic sealing film 28 can be formed of a multilayer film including these films. The organic buffer film 27 is a light-transparent organic film having a planarization effect. The organic buffer film 27 can be made of an applicable organic material such as acrylic. The organic buffer film 27 can be formed by, for example, ink-jet printing. A bank may be provided to the non-display region to stop the droplets.

The lower-face film 10 is attached to the lower face of the resin layer 12 after the support substrate has been removed. Hence, the lower-face film 10 provides the display device with excellent flexibility. The lower-face film 10 is, for example, a PET film. The functional film 39 has at least one of, for example, an adaptive optics correction function, a touch sensor function, and a protection function.

Described above is a flexible display device. If a non-flexible display device is manufactured, typical steps such as forming the resin layer and replacing base materials are unnecessary. Hence, for example, the glass substrate undergoes stacking steps of Steps S2 to S5, followed by Step S9. Moreover, if a non-flexible display device is manufactured, a light-transparent sealing member may be provided together with, or instead of, the sealing layer 6. The sealing member may be adhered with a sealing adhesive under nitrogen atmosphere. Preferably, the light-transparent sealing member can be recessed and formed of such materials as glass and plastic.

An embodiment of the disclosure relates in particularly to Step S4 of the above method for manufacturing the display device. Moreover, an embodiment of the disclosure relates in particularly to the hole-transport layer, the light-emitting layer, and the intermediate layer included in the active layer 24 in the above configuration of the display device.

### First Embodiment

Described below is an embodiment of the disclosure, with reference to the drawings. Note that shapes, sizes, and relative arrangements illustrated in the drawings are merely examples. The disclosure shall not be interpreted to a limited extent with such examples.

### Configuration of Active Layer 24

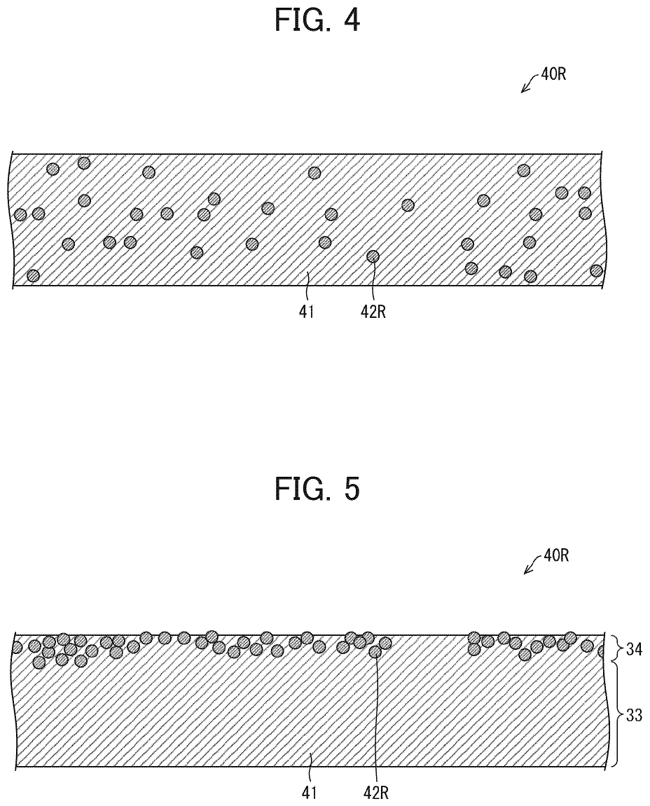

Described below with reference to FIGS. 3 and 4 is a configuration of the active layer 24 of the display device according to a first embodiment of the disclosure.

FIG. 3 is a cross-sectional view of a schematic configuration of the active layer 24 of the display device according to the first embodiment of the disclosure. FIG. 4 is a cross-sectional view showing how a red coating liquid 40R is dispersed to form a red hole-transport layer 33 and a red light-emitting layer 34 illustrated in FIG. 3. FIG. 5 is a cross-sectional view showing how the red coating liquid 40R is subjected to phase separation to form the red hole-transport layer 33 and the red light-emitting layer 34 illustrated in FIG. 3.

As illustrated in FIG. 3, the display device according to the first embodiment of the disclosure includes a plurality of pixels in the display region. Each of the pixels is provided with: at least one red sub-pixel Pr (a light-emitting element, a red light-emitting element) emitting light a color of which is red; at least one green sub-pixel Pg (a light-emitting element, a green light-emitting element) emitting light a color of which is green; and at least one blue sub-pixel Pb (a light-emitting element, a blue light-emitting element) emitting light a color of which is blue.

The active layer 24 includes: a hole-injection layer 31 covering the anode 22 and the edge cover 23; and a common hole-transport layer 32 (a second hole-transport layer, or the second hole-transport layer and a third hole-transport layer) covering the hole-injection layer 31. Each of the hole-injection layer 31 and the common hole-transport layer 32 is formed monolithically in common for the red sub-pixel Pr, the green sub-pixel Pg, and the blue sub-pixel Pb. As can be described before, each of the hole-injection layer 31 and the common hole-transport layer 32 can be omitted. The common hole-transport layer 32 may be multilayer.

If the common hole-transport layer 32 is in a single-layered structure, the common hole-transport layer 32 (the second hole-transport layer) preferably contains a hole-transport material selected from a group including poly[(9,9-dioctylfluorenyl-2,7-diyl)-co-(4,4′-(N-(4-sec-butylphenyl) diphenylamine)] (TFB) and poly[N,N′-bis(4-butylphenyl)-N,N′-bis(phenyl)-benzidine] (poly-TPD). Such a feature allows the HOMO to be formed stepwise, making it possible to improve efficiency in transporting the holes from the hole-injection layer 31 to the red hole-transport layer 33, or to the green hole-transport layer 35, or to the intermediate layer 52.

If the common hole-transport layer 32 is in a multi-layered structure, a layer (the second hole-transport layer) included in the multi-layered common hole-transport layer 32 and positioned closest to the anode 22 preferably contains a hole-transport material selected from a group including TFB and poly-TPD. Such a feature allows the HOMO to be formed stepwise, making it possible to improve efficiency in transporting the holes from the hole-injection layer 31 to the red hole-transport layer 33, to the green hole-transport layer 35, and to the intermediate layer 52.

If the common hole-transport layer 32 is in a multi-layered structure, a layer (the third hole-transport layer) included in the multi-layered common hole-transport layer 32 and positioned closest to the cathode 25 preferably contains hole-transport materials contained in the red hole-transport layer 33 and the green hole-transport layer 35. The layer included in the common hole-transport layer 32 and positioned closest to the cathode 25 has a great affinity with the red hole-transport layer 33 and the green hole-transport layer 35. Such a feature makes it possible to improve hole-transport efficiency, and interfacial adhesion, between the common hole-transport layer 32 and such layers as the red hole-transport layer 33 and the green hole-transport layer 35.

The active layer 24 further includes: the red hole-transport layer 33 (a first hole-transport layer) on the common hole-transport layer 32; and the red light-emitting layer 34 (a light-emitting layer) on the red hole-transport layer 33. Each of the red hole-transport layer 33 and the red light-emitting layer 34 is formed in the red sub-pixel Pr and shaped into an island.

The red hole-transport layer 33 is formed of a hole-transport-material monomer and a photopolymerization initiator to initiate polymerization of the hole-transport-material monomer with light. The hole-transport material can be selected from a group including, for example, OTPD(N4,N4′-Bis(4-(6-((3-ethyloxetan-3-yl)methoxy)hexyl)phenyl)-N4,N4′-diphenylbiphenyl-4,4′-diamine), QUPD(N4,N4′-Bis(4-(6-((3-ethyloxetan-3-yl)methoxy)hexyloxy)phenyl)-N4,N4′-bis(4-methoxyphenyl)biphenyl-4,4′-diamine), and X-F6-TAPC(N,N′-(4,4′-(cyclohexane-1,1-diyl)bis(4,1-phenylene))bis(N-(4-(6-(2-ethyloxetan-2-yloxy)hexyl)phenyl)-3,4,5-trifluoroaniline)). The photopolymerization initiator is, for example, a photocationic polymerization initiator. The photocationic polymerization initiator can be selected from a group including OPPI ([4-(octyloxy)phenyl]phenyliodonium·hexafluoroantimonate), diaryliodonium·special phosphorus anion salt (i.e. “IK-1”), and triarylsulfonium·special phosphorus anion salt (i.e. “CPI-410S”).

Note that the term “red” of the red hole-transport layer 33 indicates that the red hole-transport layer 33 is provided in a region of the red sub-pixel Pr. The term “red” does not indicate that the red hole-transport layer 33 is red or emits red light. The same applies to the term “green” of the green hole-transport layer 35 and the term “blue” of the blue hole-transport layer 37.

The red light-emitting layer 34 contains red quantum dots 42R emitting red light. The red quantum dots 42R may have a core/shell structure.

The red hole-transport layer 33 and the red light-emitting layer 34 are integrally and simultaneously formed of the red coating liquid 40R by phase-separation. The red coating liquid 40R is made of a resin 41 and the red quantum dots 42R mixed together. The resin 41, which is unsolidified, contains a hole-transport-material monomer and a photopolymerization initiator. As illustrated in FIG. 4, the red coating liquid 40R with the red quantum dots 42 dispersed therein is applied to the common hole-transport layer 32. Hence, as illustrated in FIG. 5, the red coating liquid 40R is phase-separated into the red light-emitting layer 34 containing the red quantum dots 42R and the red hole-transport layer 33 not containing the red quantum dots 42R. The phase-separated red coating liquid 40R is exposed to light, such that the hole-transport-material monomer is polymerized. As a result, the resin 41 is solidified. When the resin 41 is solidified, the red quantum dots 42R remain stationary. Hence, the red quantum dots 42R in the red light-emitting layer 34 are at least partially buried in the resin 41 of the red hole-transport layer 33.

As illustrated in FIG. 3, the active layer 24 further includes: the green hole-transport layer 35 (the first hole-transport layer) on the common hole-transport layer 32; and a green light-emitting layer 36 (the light-emitting layer) on the green hole-transport layer 35. Each of the green hole-transport layer 35 and the green light-emitting layer 36 is formed in the green sub-pixel Pg and shaped into an island. The green hole-transport layer 35 is formed of a hole-transport-material monomer and a photopolymerization initiator to initiate polymerization of the hole-transport-material monomer with light. The green light-emitting layer 36 contains green quantum dots emitting green light. The hole-transport material can be selected from a group including, for example, OTPD, QUPD, and X-F6-TAPC. The photopolymerization initiator is, for example, a photocationic polymerization initiator. The photocationic polymerization initiator can be selected from a group including OPPI, IK-1, and CPI-410S. The green quantum dots may have a core/shell structure.

In a similar manner as the red hole-transport layer 33 and the red light-emitting layer 34, the green hole-transport layer 35 and the green light-emitting layer 36 are integrally and simultaneously formed of the green coating liquid 40G by phase-separation. The green coating liquid 40G is made of a resin and the green quantum dots mixed together. Hence, the green quantum dots in the green light-emitting layer 36 are at least partially buried in the resin of the green hole-transport layer 35.

The active layer 24 further includes the intermediate layer 52 (a light-emitting layer of a blue light-emitting element) covering the common hole-transport layer 32, the red light-emitting layer 34, and the green light-emitting layer 36. The intermediate layer 52 is formed monolithically in common for the red sub-pixel Pr, the green sub-pixel Pg, and the blue sub-pixel Pb. If the intermediate layer 52 is thinner than 5 nm, the intermediate layer 52 might not be formed in some regions. Hence, the intermediate layer 52 has a film thickness of preferably 5 nm or thicker in order to reduce current leakage between an electron-transport layer 53 and such layers as the red hole-transport layer 33 and the green hole-transport layer 35. The intermediate layer 52 has a film thickness of preferably 30 nm or thinner in order not to keep the red light-emitting layer 34 and the green light-emitting layer 36 from emitting light. The intermediate layer 52 contains blue quantum dots 42B emitting blue light. A peak emission wavelength of the blue quantum dots 42B is shorter than peak emission wavelengths of the red quantum dots 42R and the green quantum dots. The blue quantum dots 42B may have a core/shell structure.

The intermediate layer 52 functions as a light-emitting layer in the blue sub-pixel Pb. Hence, the peak emission wavelength of the blue quantum dots 42B is preferably 450 nm or longer and 500 nm or shorter.

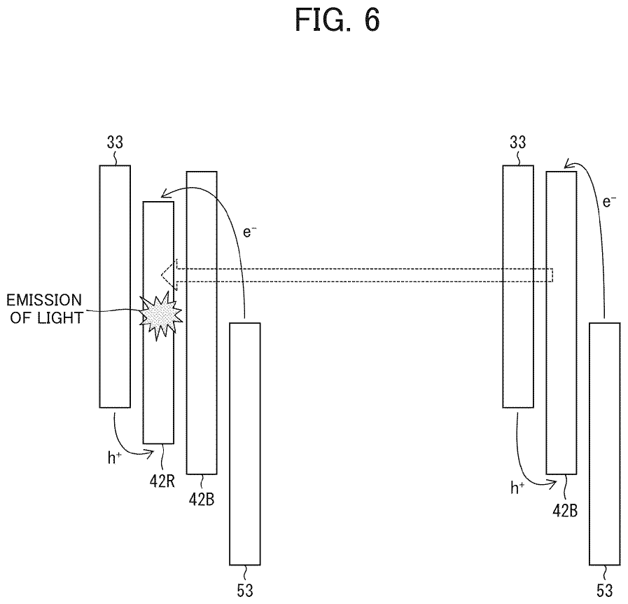

Meanwhile, the intermediate layer 52 does not function as a light-emitting layer in either the red sub-pixel Pr or the green sub-pixel Pg. This is because, as illustrated in the left of FIG. 6, the electrons are injected more preferentially into the red quantum dots 42R in the red sub-pixel Pr than into the blue quantum dots 42B. In addition, as illustrated in the right of FIG. 6, when the electrons are injected into the blue quantum dots 42B, energy of the excited blue quantum dots 42B moves to, and is absorbed into, the red quantum dots 42R, as illustrated by the arrow in broken line of FIG. 6. The same applies to the green sub-pixel Pg.

FIG. 6 is a diagram illustrating the red hole-transport layer 33 in FIG. 3, the red quantum dots 42R contained in the red light-emitting layer 34, the blue quantum dots 42B contained in the intermediate layer 52, and an energy level of the electron transport layer 53. The drawing in the left of FIG. 6 shows an energy level of a region in which the red light-emitting layer 34 is positioned between the red hole-transport layer 33 and the intermediate layer 52. The drawing in the right of FIG. 6 shows an energy level of a region in which no red light-emitting layer 34 is found between the red hole-transport layer 33 and the intermediate layer 52.

Note that, in the red sub-pixel Pr and the green sub-pixel Pg, if a drive voltage to be applied between the anode 22 and the cathode 25 is excessively high, the light to be emitted from the blue quantum dots 42B influences the colors of the light to be emitted from the red sub-pixel Pr and the green sub-pixel Pg. Hence, the drive voltages of the red sub-pixel Pr, the blue sub-pixel Pb, and the green sub-pixel Pg are preferably 5.0 V or lower. Moreover, in order for the red light-emitting layer 34, the blue sub-pixel Pb, and the green light-emitting layer 36 to emit light, the drive voltages of the red sub-pixel Pr, the blue sub-pixel Pb, and the green sub-pixel Pg are preferably 1.5 V or higher.

The active layer 24 further includes the electron-transport layer 53 covering the intermediate layer 52. The electron-transport layer 53 is formed monolithically in common for the red sub-pixel Pr, the green sub-pixel Pg, and the blue sub-pixel Pb. The cathode 25 preferably includes a metal nanowire formed of such a metal as silver. The cathode 25, preferably a common electrode, may be formed integrally together with the electron-transport layer 53. In such a case, the electron-transport layer 53 and the cathode 25 are respectively formed of, for example, nanoparticles of zinc oxide (ZnO) and a nanowire of silver (Ag).

### Manufacturing Method

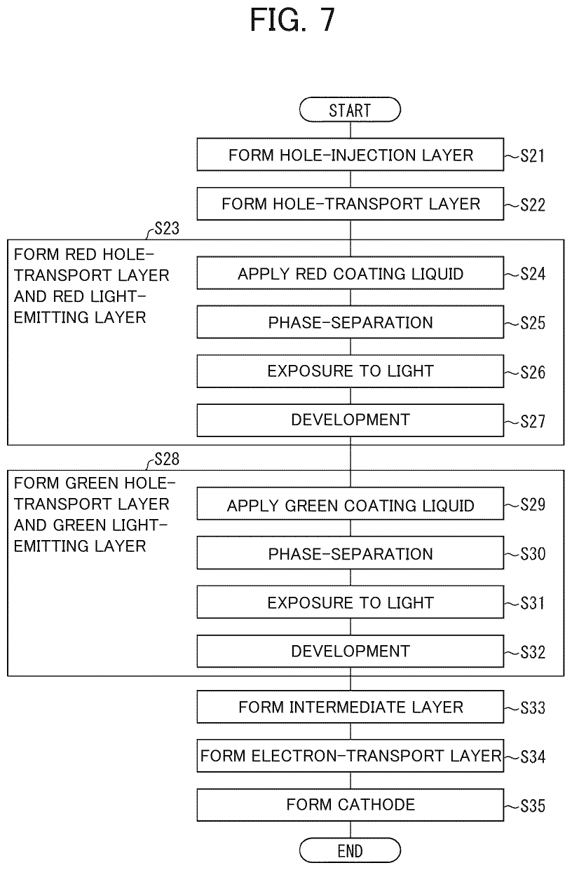

Described below with reference to FIGS. 7 to 16 is a process of forming the active layer 24 by a method for manufacturing the display device according to the first embodiment of the disclosure.

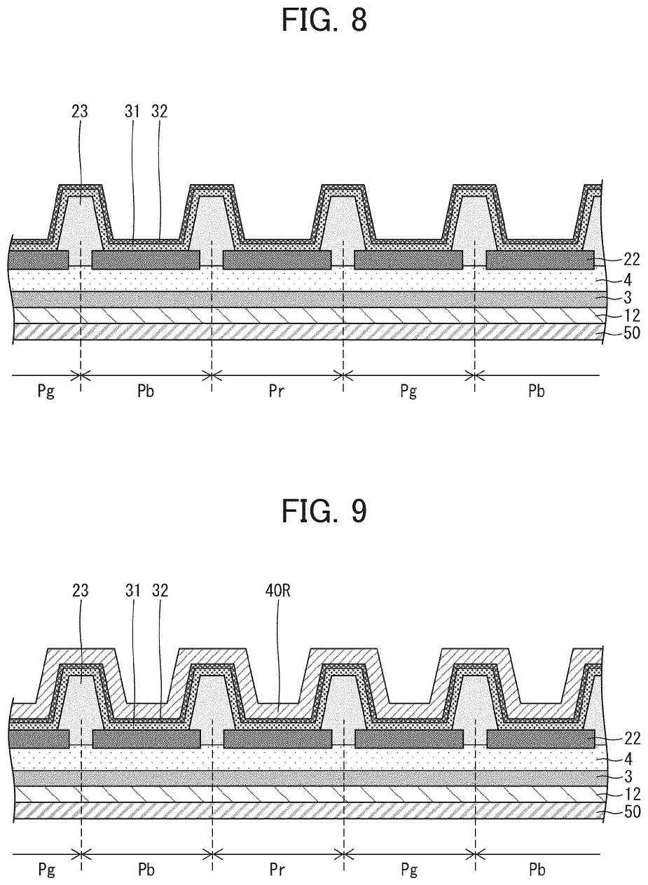

FIG. 7 is a flowchart showing the process of forming the active layer 24 illustrated in FIG. 3. FIGS. 8 to 16 are schematic cross-sectional views of the active layer 24 illustrated in FIG. 3 at steps of the forming process.

As illustrated in FIGS. 7 and 8, at START, first, a substrate is prepared. The substrate includes the resin layer 12, the barrier layer 3, the TFT layer 4, the anode 22, and the edge cover 23, all of which are formed on top of another on a support substrate 50. At Step S21, the hole-injection layer 31 is formed on the anode 22 and the edge cover 23. At Step S22, the common hole-transport layer 32 is formed on the hole-injection layer 31.

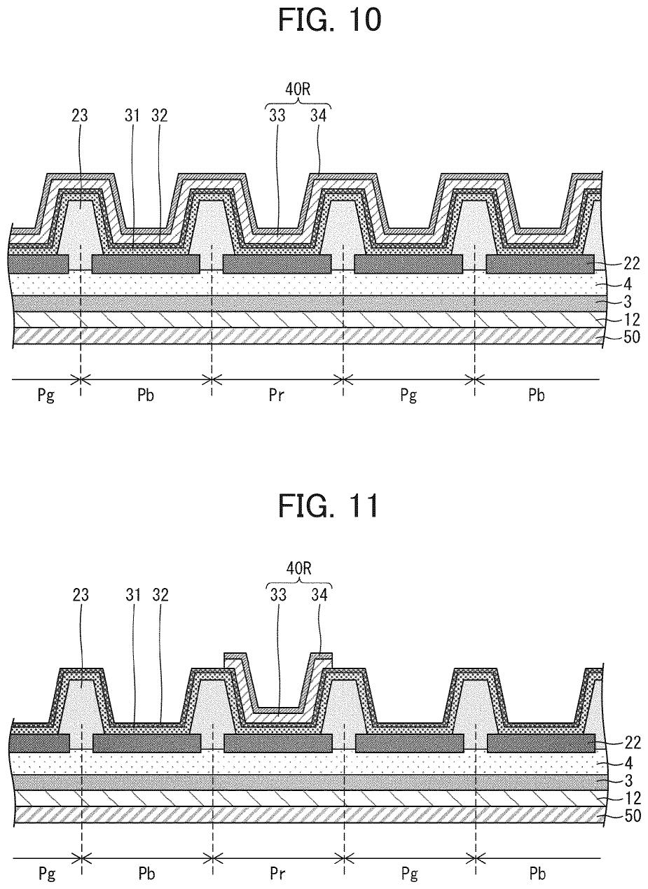

At Step S23, as illustrated in FIGS. 7 and 9 to 11, the red hole-transport layer 33 and the red light-emitting layer 34 are integrally and simultaneously formed on the common hole-transport layer 32. At Step S24 (a red application step) of Step S3, as illustrated in FIG. 9, the red coating liquid 40R containing the red quantum dots 42R and the resin 41 is monolithically applied to a region across the red sub-pixel Pr, the green sub-pixel Pg, and the blue sub-pixel Pb. At Step S25 (a red phase-separation step), as illustrated in FIG. 10, the red coating liquid 40R is left over time until the red coating liquid 40R is phase-separated into the red hole-transport layer 33 not containing the red quantum dots 42R (a layer not containing the red quantum dots) and the red light-emitting layer 34 containing the red quantum dots 42R (a layer containing the red quantum dots). At Step S26 (a red exposure step), as illustrated in FIG. 11, the red coating liquid 40R is exposed to light into a pattern by photolithography, so that a portion, of the red coating liquid 40R, in the red sub-pixel Pr solidifies, and portions, of the red coating liquid 40R, in the green sub-pixel Pg and the blue sub-pixel Pb do not solidify. At Step S27, the unsolidified portions of the red coating liquid 40R are removed, and the red hole-transport layer 33 and the red light-emitting layer 34 are developed.

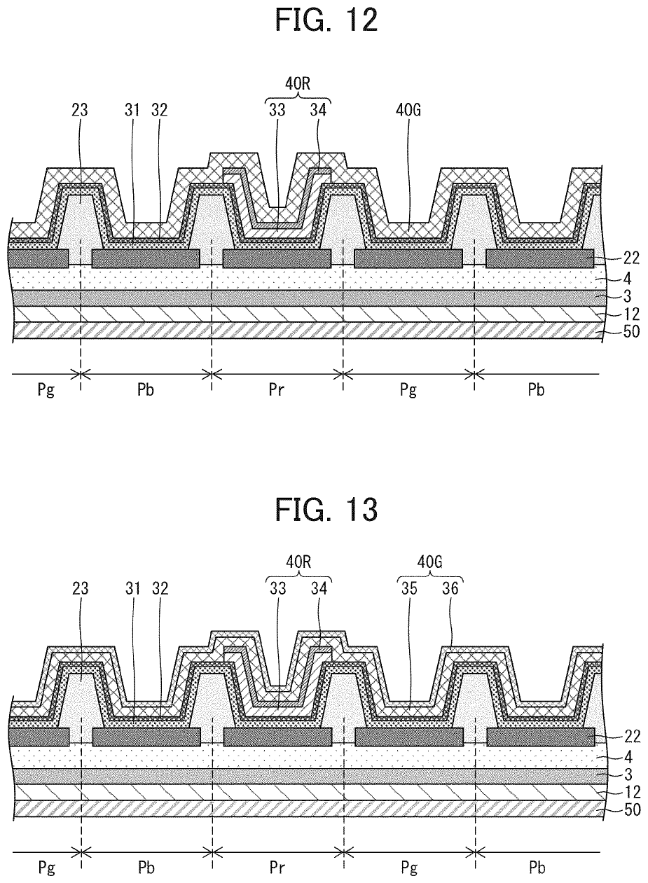

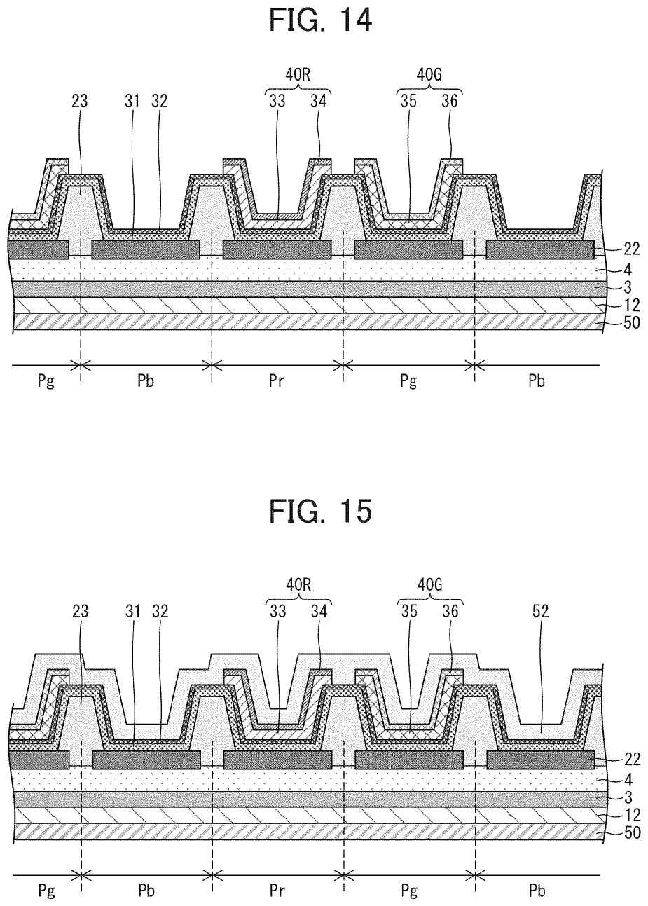

At Step S28, as illustrated in FIGS. 7 and 12 to 14, the green hole-transport layer 35 and the green light-emitting layer 36 are integrally and simultaneously formed above the substrate as seen at Step S23. At Step S29 (a green application step) of Step S28, as illustrated in FIG. 12, the green coating liquid 40G containing the green quantum dots and the resin is monolithically applied to the region across the red sub-pixel Pr, the green sub-pixel Pg, and the blue sub-pixel Pb. At Step S30 (a green phase-separation step), as illustrated in FIG. 13, the green coating liquid 40G is left over time until the green coating liquid 40G is phase-separated into the green hole-transport layer 35 not containing the green quantum dots (a layer not containing the green quantum dots) and the green light-emitting layer 36 containing the green quantum dots (a layer containing the green quantum dots). At Step S31 (a green exposure step), as illustrated in FIG. 14, the green coating liquid 40G is exposed to light into a pattern by photolithography, so that a portion, of the green coating liquid 40G, in the green sub-pixel Pg solidifies, and portions, of the green coating liquid 40G, in the red sub-pixel Pr and the blue sub-pixel Pb do not solidify. At Step S32, the unsolidified portions of the green coating liquid 40G are removed, and the green hole-transport layer 35 and the green light-emitting layer 36 are developed.

Note that Step S28 may precede Step S23.

At Step S33 (an intermediate layer forming step), as illustrated in FIGS. 7 and 15, the intermediate layer 52 containing the blue quantum dots 42B is formed above the substrate in the region across the red sub-pixel Pr, the green sub-pixel Pg, and the blue sub-pixel Pb. As an example, the blue quantum dots 42B are mixed with a volatile solvent. The solvent is monolithically applied to the region across the red sub-pixel Pr, the green sub-pixel Pg, and the blue sub-pixel Pb. After applied, the solvent is volatilized to form the intermediate layer 52. Step S33 succeeds Steps S23 and S28. Hence, the intermediate layer 52 covers the solidified portions of the red coating liquid 40R and the green coating liquid 40G.

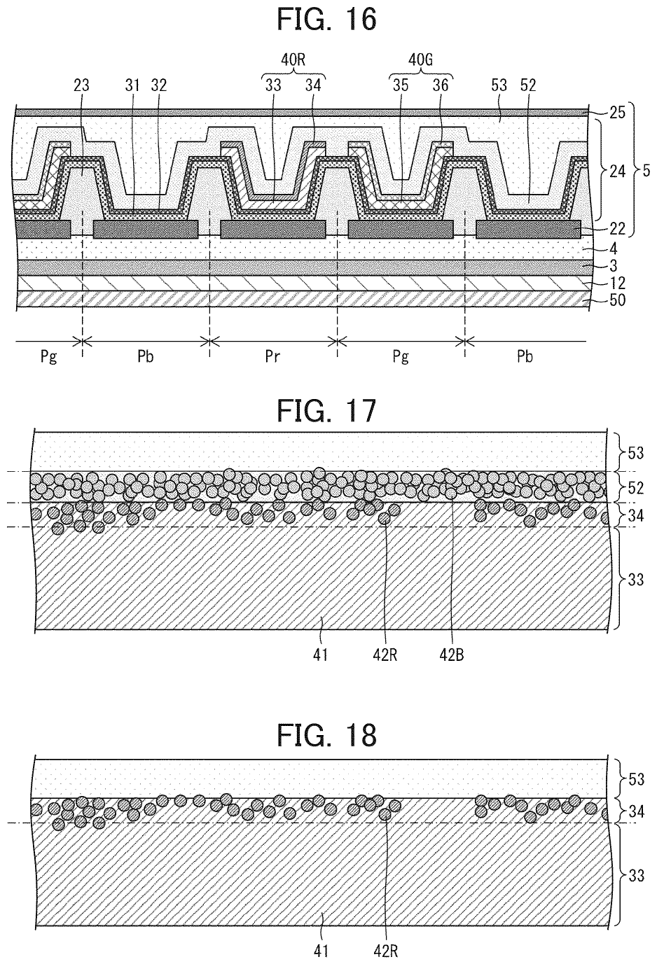

At Step S34 (an electron-transport layer forming step), as illustrated in FIGS. 7 and 16, the electron-transport layer 53 is formed above the substrate across the red sub-pixel Pr, the green sub-pixel Pg, and the blue sub-pixel Pb. At Step S35, the cathode 25 is formed. Step S34 succeeds Step S33. Hence, the electron-transport layer 53 covers the intermediate layer 52.

In the above configuration, the intermediate layer 52 is integrally formed in common for the red sub-pixel Pr and the green sub-pixel Pg. However, the scope of the disclosure shall not be limited to such a configuration. For example, the intermediate layer 52 also serving as the light-emitting layer of the blue sub-pixel Pb may be formed across the blue sub-pixel Pb and the red sub-pixel Pr, and another intermediate layer may be formed for the green sub-pixel Pg. The other intermediate layer may contain quantum dots the peak emission wavelength of which is shorter than the peak emission wavelength of the green quantum dots. For example, the intermediate layer 52 also serving as the light-emitting layer of the blue sub-pixel Pb may be formed across the blue sub-pixel Pb and the green sub-pixel Pg, and another intermediate layer may be formed for the red sub-pixel Pr. The other intermediate layer may contain quantum dots emitting light the peak emission wavelength of which is shorter than the peak emission wavelength of the red quantum dots.

### COMPARATIVE EXAMPLES AND EXAMPLES

Described below with reference to FIGS. 17 to 23 is the display device according to the first embodiment of the disclosure. However, the disclosure shall not be limited to Examples 1 to 3.

### Example 1

FIG. 17 is a cross-sectional view showing a relationship between the red light-emitting layer 34 and the electron-transport layer 53 in the light-emitting element according to Example 1.

As illustrated in FIG. 17, in the light-emitting element according to Example 1, the intermediate layer 52 is formed directly on the red light-emitting layer 34, and the electron-transport layer 53 is formed directly on the intermediate layer 52. The intermediate layer 52 according to Example 1 is formed of quantum dots whose peak emission wavelength is 427 nm. The intermediate layer 52 has a film thickness of 10 nm. The red quantum dots 42R contained in the red light-emitting layer 34 have a peak emission wavelength of 630 nm. The configuration of the light-emitting element according to Example 1 is the same as the configuration of the light-emitting element provided as the red sub-pixel Pr illustrated in FIG. 3.

### Example 2

The light-emitting element according to Example 2 is the same as the light-emitting element according to Example 1 except that the intermediate layer 52 is formed of quantum dots whose peak emission wavelength is 443 nm.

### Example 3

The light-emitting element according to Example 3 is the same as the light-emitting element according to Example 1 except that the intermediate layer 52 is formed of quantum dots whose peak emission wavelength is 471 nm.

### Comparative Example 1

FIG. 18 is a schematic cross-sectional view showing a relationship between the red light-emitting layer 34 and the electron-transport layer 53 in the light-emitting element according to Comparative Example 1.

The light-emitting element according to Comparative Example 1 is the same as the light-emitting element according to Example 1 except that the former light-emitting element includes no intermediate layer.

### Comparative Example 2

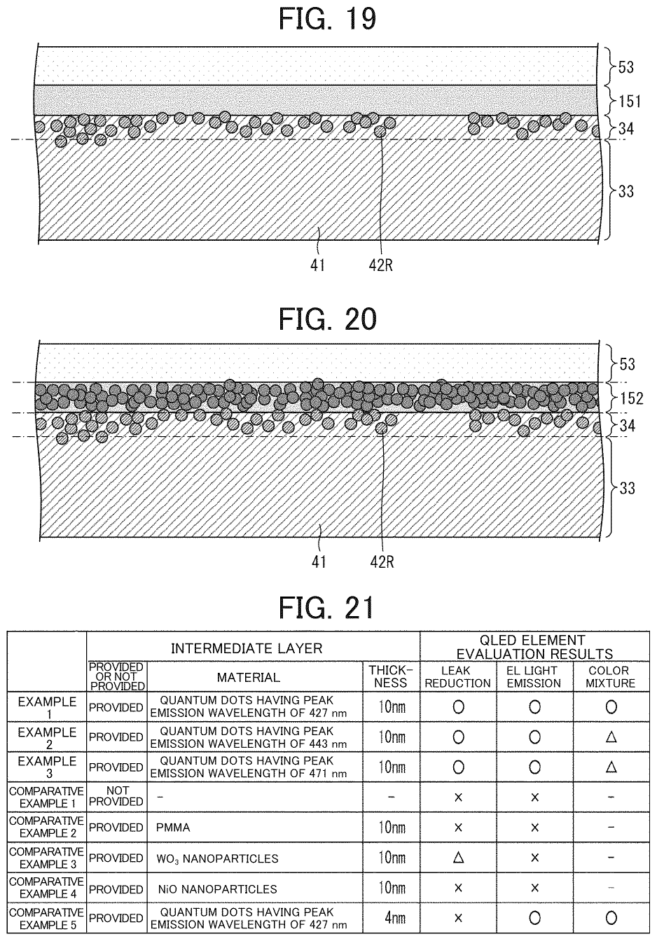

FIG. 19 is a schematic cross-sectional view showing a relationship between the red light-emitting layer 34 and the electron-transport layer 53 in the light-emitting element according to Comparative Example 2.

The light-emitting element according to Comparative Example 2 is the same as the light-emitting element according to Example 1 except that the former light-emitting element includes an intermediate layer 151 instead of the intermediate layer 52. The intermediate layer 151 is formed of poly methyl methacrylate (PMMA); that is, acrylic resin, and does not contain quantum dots. The intermediate layer 151 has a film thickness of 10 nm.

### Comparative Example 3

FIG. 20 is a schematic cross-sectional view showing a relationship between the red light-emitting layer 34 and the electron-transport layer 53 in the light-emitting element according to Comparative Example 3.

The light-emitting element according to Comparative Example 3 is the same as the light-emitting element according to Example 1 except that the former light-emitting element includes an intermediate layer 152 instead of the intermediate layer 52. The intermediate layer 152 is formed of nanoparticles of tungsten trioxide WO₃, and does not contain quantum dots. The intermediate layer 152 has a film thickness of 10 nm.

### Comparative Example 4

The light-emitting element according to Comparative Example 4 is the same as the light-emitting element according to Example 3 except that, in the former light-emitting element, the intermediate layer 152 is formed of nanoparticles of nickel oxide NiO.

### Comparative Example 5

The light-emitting element according to Comparative Example 5 is the same as the light-emitting element according to Example 1 except that, in the former light-emitting element, the intermediate layer 52 has a film thickness of 4 nm.

FIG. 21 is a table showing below evaluations of the light-emitting elements according to Examples 1 to 3 and Comparative Examples 1 to 5.

Leak Reduction: A voltage V is applied between the anode and the cathode of each of the light-emitting elements, and a density J is measured of a current running in each light-emitting element. As to the voltage-current density characteristic, the sign “○” denotes J∝V\hat{ }(5+δ₁), the sign “Δ” denotes J∝V\hat{ }(2+δ₂), and the sign “×” denotes j∝V\hat{ }(1+δ₃). Here, δ₁ is a number of 0 or more, δ₂ is a number of 0 or more and less than 3, and δ₃ is a number of 0 or more and less than 1.

EL Light Emission: The sign “○” denotes a light-emitting element in which EL light emission is confirmed when a voltage up to 5 V is applied, and the sign “×” denotes a light-emitting element in which EL light emission is not confirmed when a voltage up to 5 V is applied.

Color Mixture: A voltage is applied to the light-emitting elements whose light emission evaluation is “○”. A uv chromaticity is measured, of light emitted from each light-emitting element, at five points including the voltage at one end at which each light-emitting element starts to emit light and the voltage of 5V at the other end. A color shift (Δu′v′) is evaluated of the light emitted from each light-emitting element. The sign “Δ” denotes a light-emitting element exhibiting 0.02<Δu′v′≤0.05. The sign “○” denotes a light-emitting element exhibiting Δu′v′≤0.02. Here, Δu′v′denotes an average value of √{(u′ₓ−u′₀)\hat{ }2+(v′ₓ−v′₀)\hat{ }2)}, u′ₓ denotes u′ at each of the four voltages except the voltage observed when the light starts to emit, v′ₓ denotes v′ at each of the four points except the voltage observed when the light starts to emit, and sign v′₀ denotes v′ at the voltage observed when the light starts to emit.

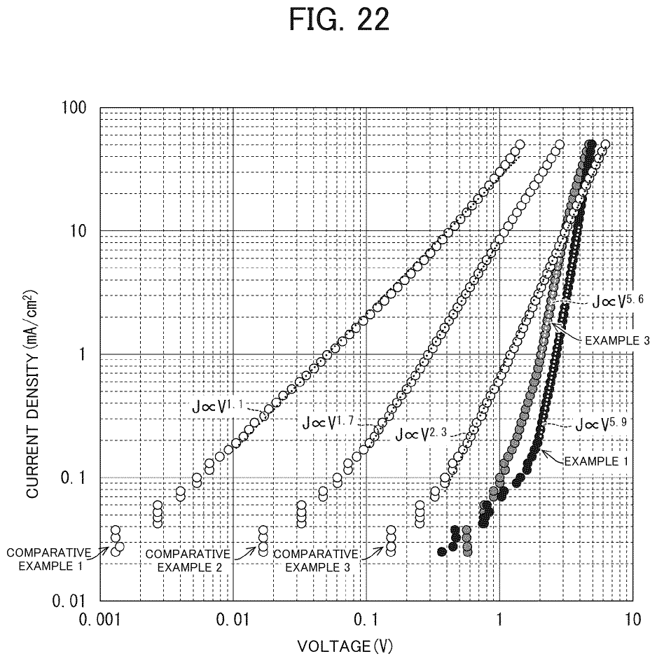

FIG. 22 is a graph showing a relationship between the applied voltage and the current density of each of the light-emitting elements according to Examples 1 and 3 and Comparative Examples 1 to 3.

FIG. 23 is a graph showing a relationship between the applied voltage and the normalized luminance of emitted light of each of the light-emitting elements according to Examples 1 and 3 and Comparative Examples 1 to 3. The luminance of the emitted light is normalized so that the normalized luminance of the emitted light is “1” when a voltage of 5.0 V is applied to the light-emitting element according to Example 1.

FIG. 21 shows that, compared with the light-emitting elements according to Comparative Examples 1 to 5, the light-emitting elements according to Examples 1 to 3 can reduce current leakage, and exhibit higher light emission efficiency. Hence, the intermediate layer 52, containing quantum dots whose peak emission wavelength is short, reduces current leakage between the electron-transport layer 53 and such layers as the common hole-transport layer 32, the red hole-transport layer 33, and the green hole-transport layer 35.

Moreover, FIGS. 22 and 23 show that, compared with the light-emitting element according to Comparative Example 3, the light-emitting element according to Example 1 can further reduce current leakage, and exhibits higher light emission efficiency. The shorter the peak emission wavelength is of the quantum dots contained in the intermediate layer 52, the higher the efficiency is in movement and absorption of energy from the intermediate layer 52 to the red light-emitting layer 34. Hence, not only the reduction of the current leakage but also the movement of the energy from the intermediate layer 52 to the red light-emitting layer 34 contribute to the high light emission efficiency of the light-emitting elements according to Examples 1 to 3.

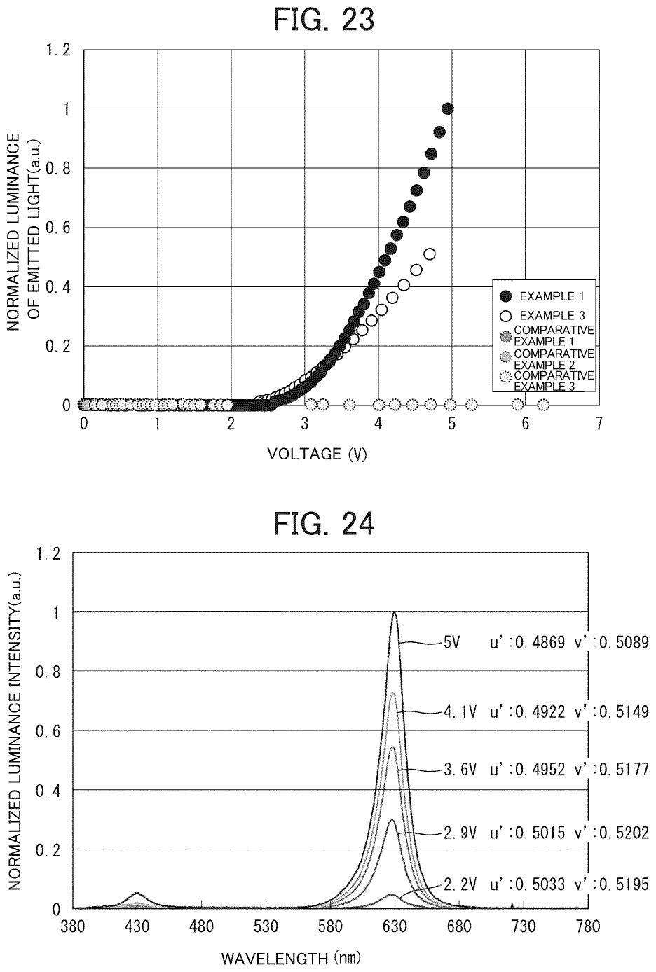

FIG. 24 is a graph of emission spectrums measured and normalized when voltages of 2.2 V, 2.9 V, 3.6 V, 4.1 V and 5.0 V are applied to the light-emitting element according to Example 1. At the voltage of 2.2 V, the light-emitting element starts to emit light. The vertical axis (luminance intensity) of the emission spectrum is normalized so that the normalized luminance intensity is “1” when a voltage of 5.0 V is applied to the light-emitting element according to Example 1.

FIG. 24 shows that, when the drive voltage is 5 V or lower, the component of the light emitted from the intermediate layer 52 (a component having a peak wavelength of 430 nm in FIG. 24) does not influence the color of the light emitted from the light-emitting element according to Example 1 in visual observation by a human being (Δu′v′≤0.02).

### Second Embodiment

Described below is another embodiment of the disclosure, with reference to the drawings. Note that, for the sake of description, like reference numerals designate identical or substantially identical components between this embodiment and the above embodiment. Such components will not be repeatedly elaborated upon here.

### Configuration of Active Layer 24

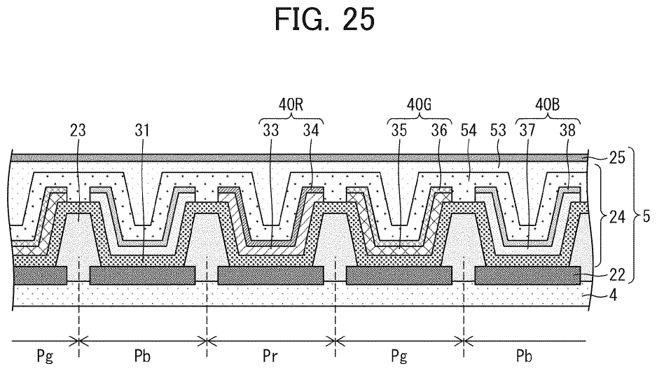

FIG. 25 is a cross-sectional view of a schematic configuration of the active layer 24 of a display device according to a second embodiment of the disclosure.

As illustrated in FIG. 25, the display device according to the second embodiment is different from the display device according to the first embodiment in that, the former display device (i) omits the intermediate layer 52 also serving as the light-emitting layer of the blue sub-pixel Pb, and (ii) includes: a blue hole-transport layer 37 (the first hole-transport layer); a blue light-emitting layer 38 (the light-emitting layer); and an intermediate layer 54. The intermediate layer 54 is separated from the blue light-emitting layer 38. The display device according to the second embodiment is different from the display device according to the first embodiment in that the former display device omits the common hole-transport layer 32. However, the display device according to the second embodiment may include the common hole-transport layer 32. Other than the above features, the display device according to the second embodiment is the same as the display device according to the first embodiment.

The blue hole-transport layer 37 is formed on the hole-injection layer 31. The blue light-emitting layer 38 is formed on the blue hole-transport layer 37. Each of the blue hole-transport layer 37 and the blue light-emitting layer 38 is formed in the blue sub-pixel Pb and shaped into an island. The blue hole-transport layer 37 is formed of a hole-transport-material monomer and a photopolymerization initiator to initiate polymerization of the hole-transport-material monomer with light. The intermediate layer 38 contains the blue quantum dots 42B emitting blue light. The hole-transport material can be selected from a group including, for example, OTPD, QUPD, and X-F6-TAPC. The photopolymerization initiator is, for example, a photocationic polymerization initiator. The photocationic polymerization initiator can be selected from a group including OPPI, IK-1, and CPI-410S.

In a similar manner as the red hole-transport layer 33 and the red light-emitting layer 34, the blue hole-transport layer 37 and the blue light-emitting layer 38 are integrally and simultaneously formed of a blue coating liquid 40B by phase-separation. The blue coating liquid 40B is made of a resin and the blue quantum dots mixed together. Hence, the blue quantum dots 42B in the blue light-emitting layer 38 are at least partially buried in the resin of the blue hole-transport layer 37.

The intermediate layer 54 covers the red light-emitting layer 34, the green light-emitting layer 36, and the blue light-emitting layer 38. The intermediate layer 54 is formed monolithically in common for the red sub-pixel Pr, the green sub-pixel Pg, and the blue sub-pixel Pb. The intermediate layer 54 has a film thickness of preferably 5 nm or thicker in order to reduce current leakage between the electron-transport layer 53 and such layers as the red hole-transport layer 33, the green hole-transport layer 35, and the blue light-emitting layer 38. The intermediate layer 54 has a film thickness of preferably 30 nm or thinner in order not to keep the red light-emitting layer 34, the green light-emitting layer 36, and the blue light-emitting layer 38 from emitting light. The intermediate layer 54 contains ultraviolet quantum dots emitting ultraviolet light. A peak emission wavelength of the ultraviolet quantum dots is shorter than peak emission wavelengths of the red quantum dots 42R, the green quantum dots, and the blue quantum dots 42B. The ultraviolet quantum dots may have a core/shell structure.

Preferably, the intermediate layer 54 does not function as a light-emitting layer in any of the sub-pixels. Hence, the peak emission wavelength of the ultraviolet quantum dots is preferably 380 nm or longer and 430 nm or shorter. Meanwhile, the shorter the peak emission wavelength is of the ultraviolet quantum dots, the more the energy moves from the ultraviolet quantum dots to be absorbed into the red quantum dots 42R, the green quantum dots, and the blue quantum dots 42B. Hence, the peak emission wavelength of the ultraviolet quantum dots is also preferably 380 nm or shorter. In such a case, if the peak emission wavelength of the ultraviolet quantum dots is excessively short, it is difficult to control the size of the ultraviolet quantum dots, and the peak wavelength is preferably 250 nm or longer.

### Manufacturing Method

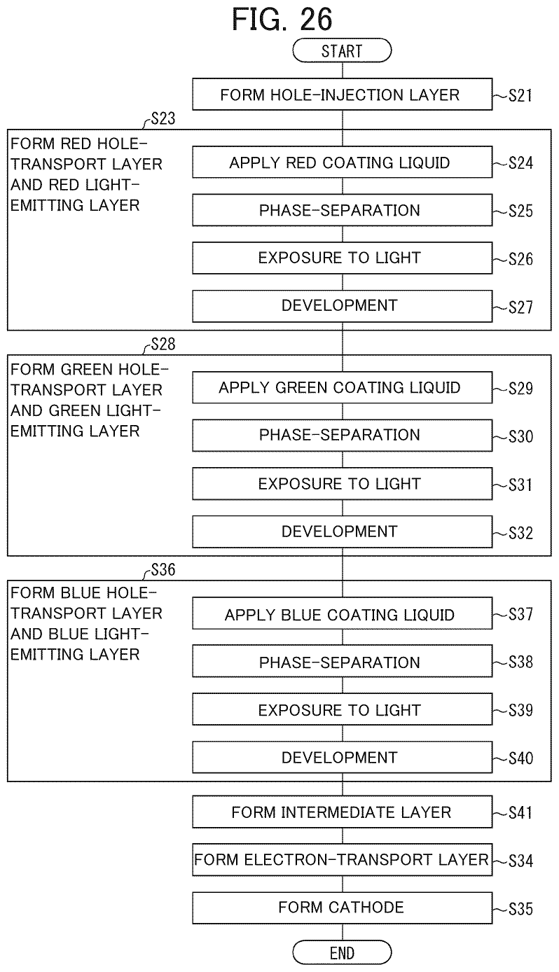

Described below with reference to FIGS. 26 to 30 is a process of forming the active layer 24 by a method for manufacturing the display device according to the second embodiment of the disclosure.

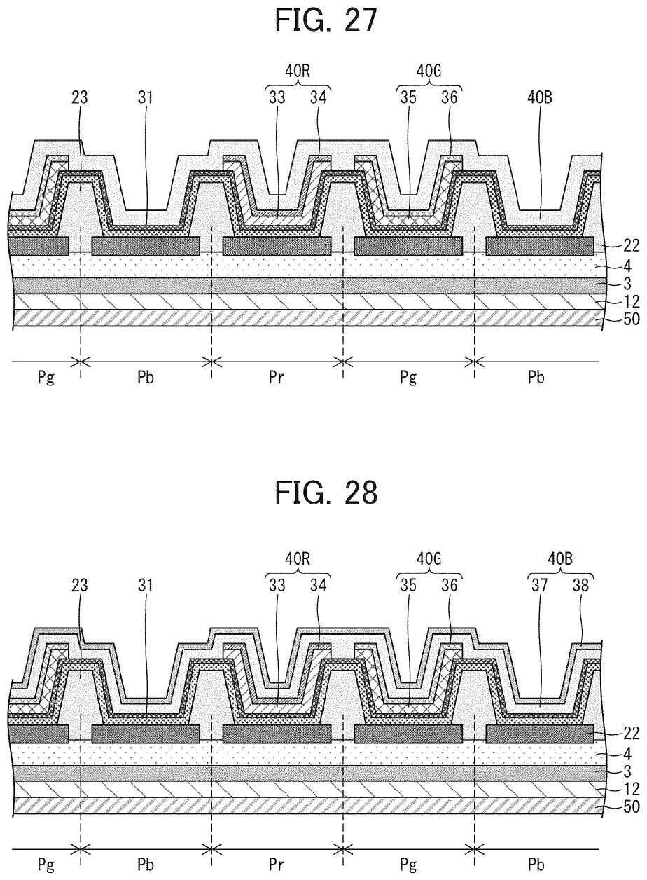

FIG. 26 is a flowchart showing the process of forming the active layer 24 illustrated in FIG. 25. FIGS. 27 to 30 are schematic cross-sectional views of the active layer 24 illustrated in FIG. 25 at steps of the forming process.

As shown in FIG. 26, first, Steps S21, S23, and S28 are carried out as those in the method for manufacturing the display device according to the first embodiment.

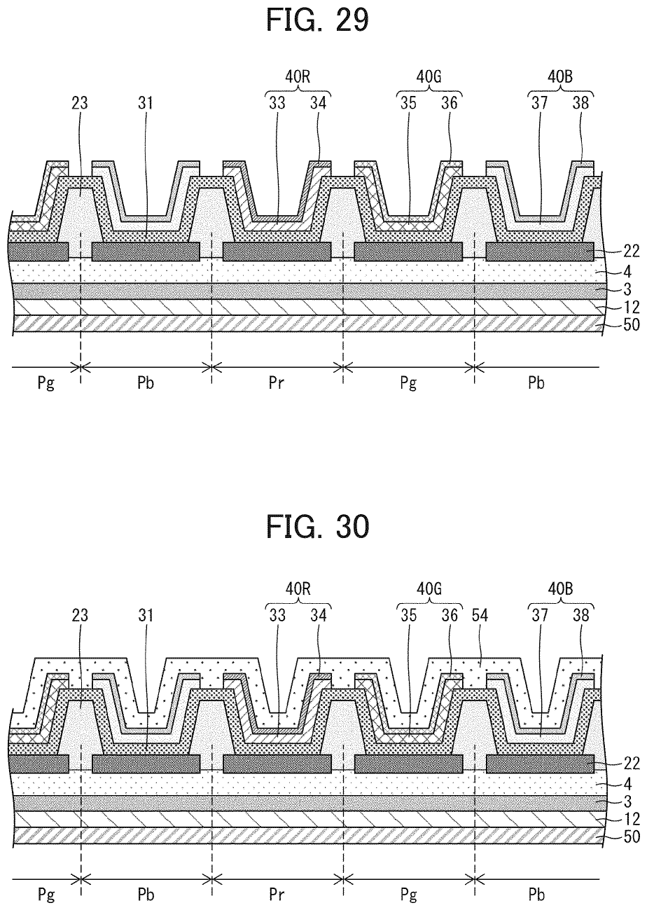

At Step S36, as illustrated in FIG. 26, and 27 to 29, the blue hole-transport layer 37 and the blue light-emitting layer 38 are integrally and simultaneously formed above the substrate as seen at Step S23. At Step S37 (a blue application step) of Step S36, as illustrated in FIG. 27, the blue coating liquid 40B containing the blue quantum dots 42B and resin is monolithically applied to a region across the red sub-pixel Pr, the green sub-pixel Pg, and the blue sub-pixel Pb. At Step S38 (a blue phase-separation step), as illustrated in FIG. 28, the blue coating liquid 40B is left over time until the blue coating liquid 40B is phase-separated into the blue hole-transport layer 37 not containing the blue quantum dots 42B (a layer not containing the blue quantum dots) and the blue light-emitting layer 38 containing the blue quantum dots (a layer containing the blue quantum dots). At Step S39 (a blue exposure step), as illustrated in FIG. 29, the blue coating liquid 40B is exposed to light into a pattern by photolithography, so that a portion, of the blue coating liquid 40B, in the blue sub-pixel Pb solidifies, and portions, of the blue coating liquid 40B, in the red sub-pixel Pr and the green sub-pixel Pg do not solidify. At Step S40, the unsolidified portions of the blue coating liquid 40B are removed, and the blue hole-transport layer 37 and the blue light-emitting layer 38 are developed.

Note that Step S36 may precede Steps S23 and S28.

At Step S41 (an intermediate layer forming step), as illustrated in FIGS. 26 and 30, the intermediate layer 54 containing the ultraviolet quantum dots is formed above the substrate in the region across the red sub-pixel Pr, the green sub-pixel Pg, and the blue sub-pixel Pb. As an example, the ultraviolet quantum dots are mixed with a volatile solvent. The solvent is monolithically applied to the region across the red sub-pixel Pr, the green sub-pixel Pg, and the blue sub-pixel Pb. After applied, the solvent is volatilized to form the intermediate layer 54. Step S21 succeeds Steps S3, S8, and S16. Hence, the intermediate layer 52 covers the solidified portions of the red coating liquid 40R, the green coating liquid 40G, and the blue coating liquid 40B.

As shown in FIG. 26, Steps S34 and S35 are carried out as those in the method for manufacturing the display device according to the first embodiment.

The intermediate layer 54 is integrally formed in common for the red sub-pixel Pr, the green sub-pixel Pg, and the blue sub-pixel Pb. However, the scope of the disclosure shall not be limited to such a configuration. For example, the intermediate layer 54 may be formed for the blue sub-pixel Pb. Another intermediate layer may be formed for the red sub-pixel Pr. The other intermediate layer may contain quantum dots a peak emission wavelength of which is shorter than a peak emission wavelength of the red quantum dots. Still another intermediate layer may be formed for the red sub-pixel Pr. The still other intermediate layer may contain quantum dots emitting light a peak emission wavelength of which is shorter than a peak emission wavelength of the green quantum dots. For example, the intermediate layer 54 may be provided only to the red sub-pixel Pr and the green sub-pixel Pg. The blue sub-pixel Pb may omit the intermediate layer, or may be provided with another intermediate layer. In such a configuration, the energy just has to easily move from the ultraviolet quantum dots contained in the intermediate layer 54 to the red quantum dots 42R and the green quantum dots. Hence, the peak emission wavelength of the ultraviolet quantum dots contained in the intermediate layer 54 is preferably 380 nm or longer and 430 nm or shorter.

### SUMMARY

A display device according to a first aspect of the disclosure includes: a display region including a plurality of pixels, and a frame region outside the display region; and a thin-film transistor layer, a light-emitting-element layer including a plurality of light-emitting elements each emitting a light in a different color, and a sealing layer sealing the light-emitting-element layer. Each of the light-emitting elements includes an anode, a first hole-transport layer, a light-emitting layer containing quantum dots, an electron-transport layer, and a cathode in a stated order. One of the anode and the cathode is an island electrode provided for each of the light-emitting elements, and another one of the anode and the cathode is a common electrode provided in common among the light-emitting elements. At least one of the light-emitting elements further includes an intermediate layer provided between the light-emitting layer and the electron-transport layer, and containing quantum dots a peak emission wavelength of which is shorter than a peak emission wavelength of the quantum dots contained in the light-emitting layer.

In the display device, of a second aspect of the disclosure, according to the first aspect, the at least one pixel may be provided with: a red light-emitting element emitting light a color of which is red; a green light-emitting element emitting light a color of which is green; and a blue light-emitting element emitting light a color of which is blue. The red light-emitting element, the green light-emitting element, and the blue light-emitting element may be included in the light-emitting elements.

In the display device, of a third aspect of the disclosure, according to the second aspect, the intermediate layer may be provided in common to the red light-emitting element, the green light-emitting element, and the blue light-emitting element.

In the display device, of a fourth aspect of the disclosure, according to the third aspect, the intermediate layer may contain the quantum dots a peak emission wavelength of which is 380 nm or longer and 430 nm or shorter.

In the display device, of a fifth aspect of the disclosure, according to the third aspect, the intermediate layer may contain the quantum dots a peak emission wavelength of which is 250 nm or longer and 380 nm or shorter.

In the display device, of a sixth aspect of the disclosure, according to the second aspect, the intermediate layer may be provided in common to the red light-emitting element and the green light-emitting element, and the light-emitting layer of the blue light-emitting element may be provided integrally with the intermediate layer.

In the display device, of a seventh aspect of the disclosure, according to the sixth aspect, the intermediate layer may contain the quantum dots a peak emission wavelength of which is 450 nm or longer and 500 nm or shorter.

In the display device, of a 6a-th aspect of the disclosure, according to the second aspect, the intermediate layer may be provided in common to the red light-emitting element and the green light-emitting element, and the light-emitting layer of the blue light-emitting element may be provided separately from the intermediate layer.

In the display device, of a 7a-th aspect of the disclosure, according to the 6a-th aspect, the intermediate layer may contain the quantum dots a peak emission wavelength of which is 380 nm or longer and 430 nm or shorter. The light-emitting layer of the blue light-emitting element may contain quantum dots a peak emission wavelength of which is 450 nm or longer and 500nm or shorter.

In the display device, of an eighth aspect of the disclosure, according to any one of the first to seventh aspects, the intermediate layer may have a film thickness of 5 nm or thicker and 30 nm or thinner.

In the display device, of a ninth aspect of the disclosure, according to any one of the first to eighth aspects, the first hole-transport layer of the at least one light-emitting element may be formed of a hole-transport-material monomer and a photopolymerization initiator.

In the display device, of a tenth aspect of the disclosure, according to the ninth aspect, the hole-transport-material monomer may be selected from the group consisting of OTPD, QUPD, and X-F6-TAPC.

In the display device, of an eleventh aspect of the disclosure, according to the ninth or the tenth aspect, the photopolymerization initiator may be a photocationic polymerization initiator.

In the display device, of a twelfth aspect of the disclosure, according to the eleventh aspect, the photocationic polymerization initiator may be selected from the group consisting of OPPI, diaryliodonium·special phosphorus anion salt, and triarylsulfonium·special phosphorus anion salt.

In the display device, of a thirteenth aspect of the disclosure, according to any one of the first to twelfth aspects, the at least one light-emitting element may further include a second hole-transport layer provided between the anode and the first hole-transport layer.

In the display device, of a fourteenth aspect of the disclosure, according to the thirteenth aspect, the second hole-transport layer may contain a hole-transport material selected from the group consisting of TFB and poly-TPD.

In the display device, of a fifteenth aspect of the disclosure, according to the thirteenth or the fourteenth aspect, the at least one light-emitting element may further include a third hole-transport layer provided between the second hole-transport layer and the first hole-transport layer.

In the display device, of a sixteenth aspect of the disclosure, according to the fifteenth aspect, the third hole-transport layer may contain a hole-transport material contained in the first hole-transport layer.

In the display device, of a seventeenth aspect of the disclosure, according to any one of the first to sixteenth aspects, the first hole-transport layer of the at least one light-emitting element may be formed so that the quantum dots contained in the light-emitting layer of the at least one light-emitting element are at least partially buried in the first hole-transport layer.

In the display device, of an eighteenth aspect of the disclosure, according to any one of the first to seventeenth aspects, the common electrode may include a metal nanowire.

In the display device, of a nineteenth aspect of the disclosure, according to any one of the eighteenth aspect, the common electrode may be the cathode, and formed integrally together with the electron-transport layer.

In a method, for manufacturing a display device, according to a twentieth aspect, the display device includes: a display region including a plurality of pixels, and a frame region outside the display region; and a thin-film transistor layer, a light-emitting-element layer including a plurality of light-emitting elements each emitting a light in a different color, and a sealing layer sealing the light-emitting-element layer. At least one of the pixels is provided with: a red light-emitting element emitting light a color of which is red; a green light-emitting element emitting light a color of which is green; and a blue light-emitting element emitting light a color of which is blue. The red light-emitting element, the green light-emitting element, and the blue light-emitting element are included in the light-emitting elements. The method includes: a red application step of applying a red coating liquid to a region of the red light-emitting element, a region of the green light-emitting element, and a region of the blue light-emitting element, the red coating liquid containing red quantum dots emitting the red light, a hole-transport material monomer, and a photopolymerization initiator; a red phase-separation step of phase-separating the red coating liquid into a layer containing the red quantum dots and a layer not containing the red quantum dots; a red exposure step of exposing, to light, the red coating liquid into a pattern, to solidify a portion, of the red coating liquid, applied to the region of the red light-emitting element; a green application step of applying a green coating liquid to the region of the red light-emitting element, the region of the green light-emitting element, and the region of the blue light-emitting element, the green coating liquid containing green quantum dots emitting the green light, a hole-transport material monomer, and a photopolymerization initiator; a green phase-separation step of phase-separating the green coating liquid into a layer containing the green quantum dots and a layer not containing the green quantum dots; a green exposure step of exposing, to light, the green coating liquid into a pattern, to solidify a portion, of the green coating liquid, applied to the region of the green light-emitting element; and an intermediate layer forming step of forming an intermediate layer to cover the portion of which the red coating liquid is solidified and the portion of which the green coating liquid is solidified, the intermediate portion containing either blue quantum dots emitting the blue light, or quantum dots a peak emission wavelength of which is shorter than a peak emission wavelength of the blue quantum dots.

In the method, of a twenty first aspect of the disclosure, according to the twentieth aspect, the intermediate layer may contain the blue quantum dots, and the blue light-emitting element may include the light-emitting layer provided integrally with the intermediate layer.

The method, of a twenty second aspect of the disclosure, according to the twentieth aspect, may further include: a blue application step of applying a blue coating liquid to the region of the red light-emitting element, the region of the green light-emitting element, and the region of the blue light-emitting element, the blue coating liquid containing the blue quantum dots, a hole-transport material monomer, and a photopolymerization initiator; a blue phase-separation step of phase-separating the blue coating liquid into a layer containing the blue quantum dots and a layer not containing the blue quantum dots; and a blue exposure step of exposing, to light, the blue coating liquid into a pattern, to solidify a portion, of the blue coating liquid, applied to the region of the blue light-emitting element. In the intermediate layer forming step, the intermediate layer may be formed to cover the portion of which the red coating liquid is solidified, the portion of which the green coating liquid is solidified, and the portion of which the blue coating liquid is solidified. The intermediate layer may contain the quantum dots the peak emission wavelength of which is shorter than the peak emission wavelength of the blue quantum dots.

The disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the disclosure. Moreover, the technical aspects disclosed in each embodiment may be combined to achieve a new technical feature.

1. A display device, comprising:
a display region including a plurality of pixels, and a frame region outside the display region; and
a thin-film transistor layer, a light-emitting-element layer including a plurality of light-emitting elements, each emitting light in a different color, and a sealing layer sealing the light-emitting-element layer, wherein
each of the plurality of light-emitting elements includes:
a red light-emitting element emitting light a color of which is red,
a green light-emitting element emitting light a color of which is green, and
a blue light-emitting element emitting light a color of which is blue,
each of the red light-emitting element, the green light-emitting element, and the blue light-emitting element includes an anode, a first hole-transport layer, a light-emitting layer containing quantum dots, an electron-transport layer, and a cathode in this stated order,
the light-emitting layer included in the red light-emitting element, the light-emitting layer included in the blue light-emitting element, and the light-emitting layer included in the green light-emitting element are separated from each other and are positioned above portions where the anode included in the red light-emitting element, the anode included in the green light-emitting element, and the anode included in the blue light-emitting element are separated,
one of the anode and the cathode is an island electrode provided for each of the plurality of light-emitting elements, and another one of the anode and the cathode is a common electrode provided in common among the plurality of light-emitting elements,
each of the red light-emitting element, the green light-emitting element and the blue light-emitting element includes an intermediate layer in common provided between the light-emitting layer and the electron-transport layer, and containing quantum dots a peak emission wavelength of which is shorter than a peak emission wavelength of the quantum dots contained in the light-emitting layer.

2. The display device according to claim 1, wherein
the intermediate layer contains the quantum dots a peak emission wavelength of which is 380 nm or longer and 430 nm or shorter.

3. The display device according to claim 1, wherein
the intermediate layer contains the quantum dots a peak emission wavelength of which is 250 nm or longer and 380 nm or shorter.

4. The display device according to claim 1, wherein
the intermediate layer has a film thickness of 5 nm or thicker and 30 nm or thinner.

5. The display device according to claim 1, wherein
the first hole-transport layer of the at least one of the plurality of light-emitting elements is formed of a hole-transport-material monomer and a photopolymerization initiator.

6. The display device according to claim 5, wherein
the photopolymerization initiator is a photocationic polymerization initiator, and
the photocationic polymerization initiator is selected from the group consisting of OPPI, diaryliodonium·special phosphorus anion salt, and triarylsulfonium·special phosphorus anion salt.

7. The display device according to claim 1, wherein
the first hole-transport layer of the at least one of the plurality of light-emitting elements is formed such that the quantum dots contained in the light-emitting layer of the at least one of the plurality of light-emitting elements are at least partially buried in the first hole-transport layer.

8. The display device according to claim 1, wherein
the common electrode includes a metal nanowire.

9. The display device according to claim 8, wherein
the common electrode is the cathode, and formed integrally together with the electron-transport layer.

10. A method for manufacturing a display device, the display device including:
a display region including a plurality of pixels, and a frame region outside the display region; and
a thin-film transistor layer, a light-emitting-element layer including a plurality of light-emitting elements, each emitting light in a different color, and a sealing layer sealing the light-emitting-element layer,
each of the plurality of light-emitting elements includes:
a red light-emitting element emitting light a color of which is red,
a green light-emitting element emitting light a color of which is green, and
a blue light-emitting element emitting light a color of which is blue,
the method comprising:
applying a red coating liquid to a region of the red light-emitting element, a region of the green light-emitting element, and a region of the blue light-emitting element, the red coating liquid containing red quantum dots emitting red light, a hole-transport material monomer, and a photopolymerization initiator;
phase-separating the red coating liquid into a layer containing the red quantum dots and a layer not containing the red quantum dots;
exposing, to light, the red coating liquid into a pattern, to solidify a portion, of the red coating liquid, applied to the region of the red light-emitting element;
applying a green coating liquid to the region of the red light-emitting element, the region of the green light-emitting element, and the region of the blue light-emitting element, the green coating liquid containing green quantum dots emitting green light, a hole-transport material monomer, and a photopolymerization initiator;
phase-separating the green coating liquid into a layer containing the green quantum dots and a layer not containing the green quantum dots;
exposing, to light, the green coating liquid into a pattern, to solidify a portion, of the green coating liquid, applied to the region of the green light-emitting element; and
forming an intermediate layer to cover the portion of which the red coating liquid is solidified and the portion of which the green coating liquid is solidified, the intermediate layer containing either blue quantum dots emitting blue light, or quantum dots a peak emission wavelength of which is shorter than a peak emission wavelength of the blue quantum dots, wherein
each of the red light-emitting element, the green light-emitting element, and the blue light-emitting element includes an anode, a first hole-transport layer, a light-emitting layer containing quantum dots, an electron-transport layer, and a cathode in this stated order,
the light-emitting layer included in the red light-emitting element, the light-emitting layer included in the blue light-emitting element, and the light-emitting layer included in the green light-emitting element are separated from each other and are positioned above portions where the anode included in the red light-emitting element, the anode included in the green light-emitting element, and the anode included in the blue light-emitting element are separated, and
the method further comprises:
a blue application step of applying a blue coating liquid to the region of the red light-emitting element, the region of the green light-emitting element, and the region of the blue light-emitting element, the blue coating liquid containing the blue quantum dots, a hole-transport material monomer, and a photopolymerization initiator;
a blue phase-separation step of phase-separating the blue coating liquid into a layer containing the blue quantum dots and a layer not containing the blue quantum dots; and
a blue exposure step of exposing, to light, the blue coating liquid into a pattern, to solidify a portion, of the blue coating liquid, applied to the region of the blue light-emitting element, wherein
in the intermediate layer forming step, the intermediate layer is formed to cover the portion of which the red coating liquid is solidified, the portion of which the green coating liquid is solidified, and the portion of which the blue coating liquid is solidified, the intermediate layer containing the quantum dots the peak emission wavelength of which is shorter than the peak emission wavelength of the blue quantum dots.

11. A display device, comprising:
a display region including a plurality of pixels, and a frame region outside the display region; and
a thin-film transistor layer, a light-emitting-element layer including a plurality of light-emitting elements, each emitting light in a different color, and a sealing layer sealing the light-emitting-element layer, wherein
each of the plurality of light-emitting elements includes:
a red light-emitting element emitting light a color of which is red,
a green light-emitting element emitting light a color of which is green, and
a blue light-emitting element emitting light a color of which is blue,
each of the red light-emitting element, the green light-emitting element, and the blue light-emitting element includes an anode, a first hole-transport layer, a light-emitting layer containing quantum dots, an electron-transport layer, and a cathode in this stated order,
one of the anode and the cathode is an island electrode provided for each of the plurality of light-emitting elements, and another one of the anode and the cathode is a common electrode provided in common among the plurality of light-emitting elements,
at least one of the plurality of light-emitting elements further includes an intermediate layer provided between the light-emitting layer and the electron-transport layer, and containing quantum dots a peak emission wavelength of which is shorter than a peak emission wavelength of the quantum dots contained in the light-emitting layer,
the first hole-transport layer of the at least one of the plurality of light-emitting elements is formed of a hole-transport-material monomer and a photopolymerization initiator, and
the light-emitting layer included in the red light-emitting element, the light-emitting layer included in the blue light-emitting element, and the light-emitting layer included in the green light-emitting element are separated from each other and are positioned above portions where the anode included in the red light-emitting element, the anode included in the green light-emitting element, and the anode included in the blue light-emitting element are separated.
